(19) United States
(12) Patent Application Publication
(10) Pub. No.: US 2023/0236509 A1
(43) Pub. Date: Jul. 27, 2023

(54) A SPIN COATING COMPOSITION COMPRISING A CARBON MATERIAL, A METAL ORGANIC COMPOUND, AND SOLVENT, AND A MANUFACTURING METHOD OF A METAL OXIDE FILM ABOVE A SUBSTRATE

(71) Applicant: Merch Patent GmbH, Darmstadt (DE)

(72) Inventors: Takashi SEKITO, Kakegawa-shi (JP); Joon Yeon CHO, Branchburg, NJ (US)

(21) Appl. No.: 17/918,916

(22) PCT Filed: Apr. 14, 2021
(86) PCT No.: PCT/EP2021/059603

§ 371 Date: Oct. 14, 2022

Related U.S. Application Data
(60) Provisional application No. 63/011,589, filed on Apr. 17, 2020.

(51) Int. Cl. G03F 7/11; G03F 7/16; H01L 21/768

(52) U.S. Cl. CPC G03F 7/11; G03F 7/162; H01L 21/76804; H01L 21/76877

(57) ABSTRACT

The present invention pertains to a spin coating composition comprising a carbon material and a metal organic compound. The invention also pertains to a method of using the same to form a metal oxide film above a substrate and manufacturing a device.

### FIELD OF INVENTION

The present invention relates to a spin coating composition comprising a carbon material and a metal organic compound and a method of suing the same to form a metal oxide film above a substrate. The present invention further relates to a method of manufacturing a device using the composition.

### BACKGROUND

Metal oxide films are useful in a variety of applications, for example lithographic hard masks, underlayers for anti-reflective coatings and electro-optical devices in the semiconductor fields.

As an example, photoresist (“resist”) compositions are used in microlithography processes for making miniaturized electronic components such as in the fabrication of computer chips and integrated circuits. Generally, a thin coating of a resist composition is applied to a substrate, such as a silicon wafer used for making integrated circuits. The coated substrate is then baked to remove a desired amount of solvent from the resist. The resist film on the substrate is then image-wise exposed to actinic radiation, such as, visible, ultraviolet, extreme ultraviolet, electron beam, particle beam and X-ray radiation and developed to form a pattern. The radiation causes a chemical transformation in the exposed areas of the resist. The exposed coating is treated with a developer solution to dissolve and remove either the radiation-exposed or the unexposed areas of the resist.

The trend towards the miniaturization of semiconductor devices has led to the use of new resists that are sensitive to shorter and shorter wavelengths of radiation and has also led to the use of sophisticated multilevel systems to overcome difficulties associated with such miniaturization.

Underlayers containing high amount of heat resistant elements can be used as hard masks as well as antireflective coatings. Hard masks are useful when the overlying resist is not capable of providing high enough resistance to dry etching that is used to transfer the image into the underlying semiconductor substrate. In such circumstances a material called a hard mask is used whose etch resistance is high enough to transfer any patterns created over it into the underlying semiconductor substrate. This is made possible because the organic resist is different than the underlying hard mask and it is possible to find an etch gas mixture which will allow the transfer of the image in the resist into the underlying hard mask. This patterned hard mask can then be used with appropriate etch conditions and gas mixtures to transfer the image from the hard mask into the semiconductor substrate, a task which the resist by itself with a single etch process could not have accomplished.

Under these circumstances, compositions comprising a multi-ligand substituted metal compound and a solvent were studied, which are useful as air stable precursors to high K metal oxides and can make metal hard mask film. See, e.g., Patent Literature 1.

To provide a compound with good heat resistance, and a coating capable of good filling into gaps, good planarization and reducing film shrinkage, certain organic carbon materials were studied. See, e.g., Patent Literature 2.

### CITATION LIST

[Patent Literature 1] WO2019/048393A1
[Patent Literature 2] WO2019/121480A1

### SUMMARY OF INVENTION

### Technical Problem

It has been found that there are still one or more considerable problems for which improvement are desired, including: solubility of solute is insufficient; heat resistance of solutes is insufficient; cracking can be found in a metal oxide film; etch resistance of a metal oxide film is insufficient; precipitation can happen during preparation; a density of a metal oxide film is low; coatability of a composition and/or a metal oxide film is insufficient; patterns of metal oxide film are not easily removed from the substrate; intermixing of a metal oxide film with adjacent coating can happen; a fine patterning of the metal oxide film is difficult; gap filling of a composition is insufficient; surface planarity of the film is insufficient; the hardness of the film is insufficient; internal stress of the film is high; pattern wiggling often happens.

The invention described below solves at least one of these problems.

### Solution to Problem

The present invention provides a spin coating composition comprising a carbon material (A), a metal organic compound (B), and solvent (C), wherein the carbon material (A) comprises unit (A1) represented by formula (A1):

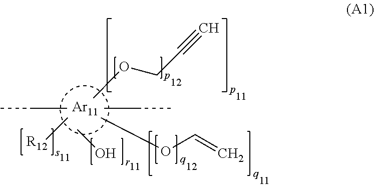

where
Ar₁₁ is C₆₋₆₀ hydrocarbon unsubstituted or substituted by R₁₁;
R₁₁ is C₁₋₂₀ linear, branched or cyclic alkyl, amino, or alkylamino;
R₁₂ is I, Br or CN;
p₁₁ is number of 0-5, p₁₂ is number of 0-1, q₁₁ is number of 0-5, q₁₂ is number of
0-1, r₁₁ is number of 0-5, and s₁₁ is number of 0-5, provided that p₁₁, q₁₁ and r₁₁ doesn't take 0 at the same time;
the solvent (C) comprises an organic solvent; and
the mass ratio of the carbon material (A) to the mass of the metal organic compound (B) is approximately 5 to approximately 100 mass %.

In another embodiment, the composition consists essentially of components (A), (B) and (C) as described above. In such an embodiment, the combined amounts of (A), (B) and (C) do not necessarily equal 100% by weight, and can include other ingredients (e.g., additional solvent(s), including water, common additives and/or impurities) that do not materially change the effectiveness of the composition.

In another embodiment, the composition consists of components (A), (B) and (C) as described above. In such an embodiment, the combined amounts of (A), (B) and (C) equal approximately 100% by weight but may include other small and/or trace amounts of additives that are present in such small quantities that they do not materially change the effectiveness of the composition. For example, in one such embodiment, the composition can contain 2% by weight or less of additives. In another embodiment, the composition can contain 1% by weight or less than of additives. In a further embodiment, the composition can contain 0.05% by weight or less than of additives

This invention also provides a spin on metal hard mask composition.

This invention provides a method of manufacturing a metal oxide film comprising (1) spin coating the spin coating composition above on a substrate; and (2) heating the spin coating composition to make a metal oxide film.

This invention provides a method of manufacturing a resist coating comprising: (3) applying a resist composition above the metal oxide film manufactured as above.

This invention provides a method of manufacturing resist patterns comprising: (4) exposing the resist coating manufactured as above by radiation light; (5) developing the exposed resist coating by developer; and (6) removing the developer from the substrate.

This invention provides a method of manufacturing processed substrate comprising: (7) etching with the resist patterns manufactured as above; and (8) processing the substrate.

This invention provides a method of manufacturing a device comprising the manufacturing method of processed substrate as above.

### Effects of the Invention

The solutes in the spin coating composition exhibits good solubility in solvent (C). The solutes in the spin coating composition exhibits good heat resistance. The metal oxide film made from the spin coating composition reduces cracking. The metal oxide film made from the spin coating composition exhibits good etch resistance. The solutes of the spin coating composition reduce precipitation. The metal oxide film increases its density. The metal oxide film exhibits good coatability on a substrate. The patterns of metal oxide film once used as a mask can be removed easily. The metal oxide film reduces intermixing with adjacent coating (e.g., resist coating). A fine patterning of the metal oxide film is possible. The spin coating composition exhibits good gap fill property. The metal oxide film have good planarization. The metal oxide film have high hardness. It is possible to inhibit internal stress becoming too high and/or pattern wiggling.

### DESCRIPTION OF EMBODIMENTS

The above summary and the following details are provided for illustration of the present invention and are not intended to limit the claimed invention.

### DETAILED DESCRIPTION

### Definitions

Throughout this specification, below defined symbols, units, abbreviations and terms have the meanings given in below definitions, descriptions and examples, unless explicitly limited or stated.

The use of the singular includes the plural, and the words “a,” “an” and “the” mean “at least one.” Furthermore, the use of the term “including,” as well as other forms such as “includes” and “included,” is not limiting. Also, terms such as “element” or “component” encompass both elements or components comprising one unit and elements or components that comprise more than one unit.

The term “and/or” refers to any combination of the any foregoing elements including using a single element.

When a numerical range is specified herein using “−,” “to” or “˜,” the numerical range includes both of the numbers indicated before and after “−,” “to” or “˜” and the unit is the same for the two numbers. For example, “5-25 mol %” means “5 mol % or more and 25 mol % or less.”

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

The terms such as “C_{x-y},” “Cₓ—C_{y},” and “Cₓ” as used herein represent the number of carbon atoms in a molecule or substituent. For example, “C₁₋₆ alkyl” refers to an alkyl chain having 1-6 carbon atoms (such as methyl, ethyl, propyl, butyl, pentyl, hexyl and so on).

When a polymer as described herein has plural types of repeating units, these repeating units are copolymerized. The copolymerization may be anyone selected from alternating copolymerization, random copolymerization, block copolymerization, graft copolymerization, and any combination of any of these. When a polymer or resin is represented by a chemical structure, n, m and so on put down with brackets means repeating numbers.

The unit of temperatures as indicated herein is degree Celsius. For example, “20 degrees” means “20 degrees Celsius.”

Spin Coating Composition

This invention provides a spin coating composition comprising a carbon material (A), a metal organic compound (B), and solvent (C). The mass ratio of the carbon material (A) to the mass of the metal organic compound (B) is approximately 5 to approximately 100 mass %; preferably approximately 10 to approximately 75 mass %; more preferably approximately 10 to approximately 50 mass %. In a further embodiment, the spin coating composition consists essentially of these components. In yet a further embodiment, the spin coating composition consists of these components.

As another aspect, this invention provides a use of a composition to spin coat; preferably above a substrate; more preferably on a substrate. This invention provides a use of a composition to spin coat above substrate to make a coating; preferably to become film in later.

In a preferred embodiment, a spin on metal hard mask composition can consist essentially of the spin coating composition of the invention. In another preferred embodiment, a spin on metal hard mask composition can consist of the spin coating composition of the invention. It can be said that a film in later made by the composition of the invention is preferably a metal hard mask film.

After all components are added into solvent (C) and confirmed dissolved, the resultant composition can be filtrated to remove impurity and/or small debris. Known filter can be used in the preparation.

Carbon Material (A), Unit (A1)

The carbon material (A) of the invention comprise unit (A1) represented by formula (A1):

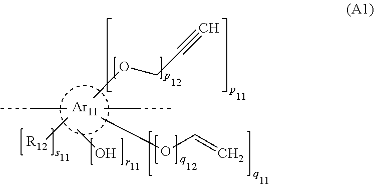

In (A1), Ar₁₁ is a C₆₋₆₀ hydrocarbon unsubstituted or substituted by R₁₁. Preferably Ar₁₁ excludes fused aromatic rings. Ar₁₁ is preferably 9,9-diphenylfluorene, 9-phenylfluorene, phenyl, a C₆₋₆₀ linear polyphenylene, or a branched polyphenylene, which can be substituted by R₁₁ each independently.

R₁₁ is a C₁₋₂₀ linear, branched or cyclic alkyl, amino, or alkylamino. R₁₁ is preferably a C₁₋₁₀ linear, branched or cyclic alkyl, or alkylamino; more preferably a C₁₋₃ linear alkyl, cyclopentyl, cyclohexyl, or dimethylamino.

When the carbon material (A) is comprised of multiple (A1) units, R₁₁ can intervene and bind unit (A1)s as a linker. There can be a single or plurality of (preferably single of) R₁₁(s) substituting one Ar₁₁.

In one unit (A1), a group surrounded by brackets (for example, a group surrounded by brackets which p₁₁ put down with) can bind to R₁₁. In such case, R₁₁ intervenes and bind the group and Ar₁₁ as a linker.

R₁₂ is I, Br or CN; preferably I or Br; more preferably I.

p₁₁ is number of 0-5. It can be one embodiment of the invention that the carbon material (A) constitutes of 2 kinds of unit (A1)s one by one, both Ar₁₁s are phenyl, p₁₁ on one Ar₁₁ is 1, and p₁₁ on another Ar₁₁ is 2. In such case, p₁₁=1.5 as whole. In this specification, the same numbering convention is utilized unless specifically stated otherwise.

p₁₁ is preferably 0, 1, 2 or 3; more preferably 0, 1 or 2; further preferably 1. p₁₁=0 is also one aspect of this invention.

p₁₂ is number of 0-1; preferably 0 or 1; more preferably 1.

q₁₁ is number of 0-5; preferably 0, 1, 2 or 3; more preferably 0, 1 or 2; further preferably 1. q₁₁=0 is also one aspect of this invention.

q₁₂ is number of 0-1; preferably 0 or 1; more preferably 1.

r₁₁ is number of 0-5; preferably 0, 1, 2 or 3; more preferably 0, 1 or 2; further preferably 1. r₁₁=0 is also one aspect of this invention.

s₁₁ is number of 0-5; preferably 0, 1, 2 or 3; more preferably 0, 1 or 2; further preferably 1. s₁₁=0 is also one aspect of this invention.

p₁₁, q₁₁ and r₁₁ doesn't take 0 at the same time.

The unit (A1) according to the invention can be unit (A1-1), (A1-2) and/or (A1-3) represented by formula (A1-1), (A1-2) and/or (A1-3). Detailed descriptions for each follow.

As one embodiment, preferably formula (A1) is formula (A1-1). Without wishing to be bound by theory, it is believed that unit (A1-1) in the carbon material (A) can contribute solubility and/or can avoid precipitation.

Unit (A1-1) is represented by formula (A1-1):

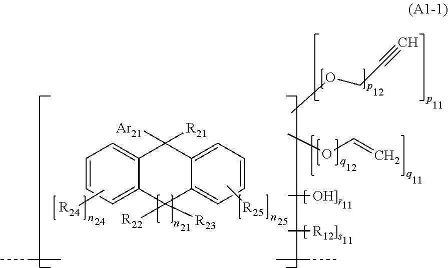

Ar₂₁ is a C₆₋₅₀ aromatic hydrocarbon ring; preferably a phenyl. Without wishing to be bound by theory, it is believed when Ar₂₁ is phenyl good effects can be expected such as solubility of the carbon material (A) and the ability to form thick films (for example≥approximately 1 micrometer, more preferably ≥approximately 1.5 micrometer) and so on.

R₂₁, R₂₂ and R₂₃ are each independently a C₆₋₅₀ aromatic hydrocarbon ring, hydrogen or single bond bonding to another unit; preferably each are independently a phenyl, hydrogen or single bond bonding to another unit; more preferably each are independently a phenyl, or single bond boding to another unit; further preferably each are independently a phenyl.

The term “another unit” of “single bond bonding to another unit” does not comprise one unit which the single bond exists in. But in the case that the carbon material (A) has plural unit (A1)s, the single bond can bond to another unit (A1) (not unit (A1) which the single bond exists in, not self-crosslinking in one unit (A1)). Unless specifically stated, the same convention applies hereinafter in this specification.

R₂₄ and R₂₅ are each independently a C₁₋₄ alkyl, optionally plural R₂₄s and/or R₂₅s can bind each other to make an aromatic ring with adjacent benzene. For example, 2 R₂₄s can bind each other to make a naphthyl ring with adjacent benzene.

n₂₁ is an integer of 0-1; preferably 0.

n₂₄ and n₂₅ are each independently an integer of 0-3; preferably 0, 1 or 2; more preferably 0 or 2, further preferably 0.

Definitions and/or embodiments of R₁₂, p₁₁, p₁₂, q₁₁, q₁₂, r₁₁ and s₁₁ are each independently the same as described above.

For example, the below left compound is a carbon material (A) that can be construed as consisting of 1 unit (A1) and 1 unit (A2), where Ar₁₁ is 9,9-diphenylfluorene, p₁₁=2, p₁₂₌₁, q₁₁=r₁₁=s₁₁=0. As shown in below right, the bonding indicated by arrow is not used to bond to another unit. Cy₅₁ in formula (A2) is 9-phenylfluorene.

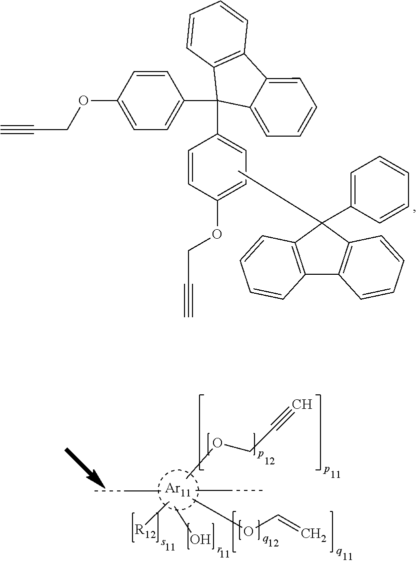

Without intending to limit the scope of the invention, exemplified embodiments of the carbon material (A) comprising unit (A1-1) include.

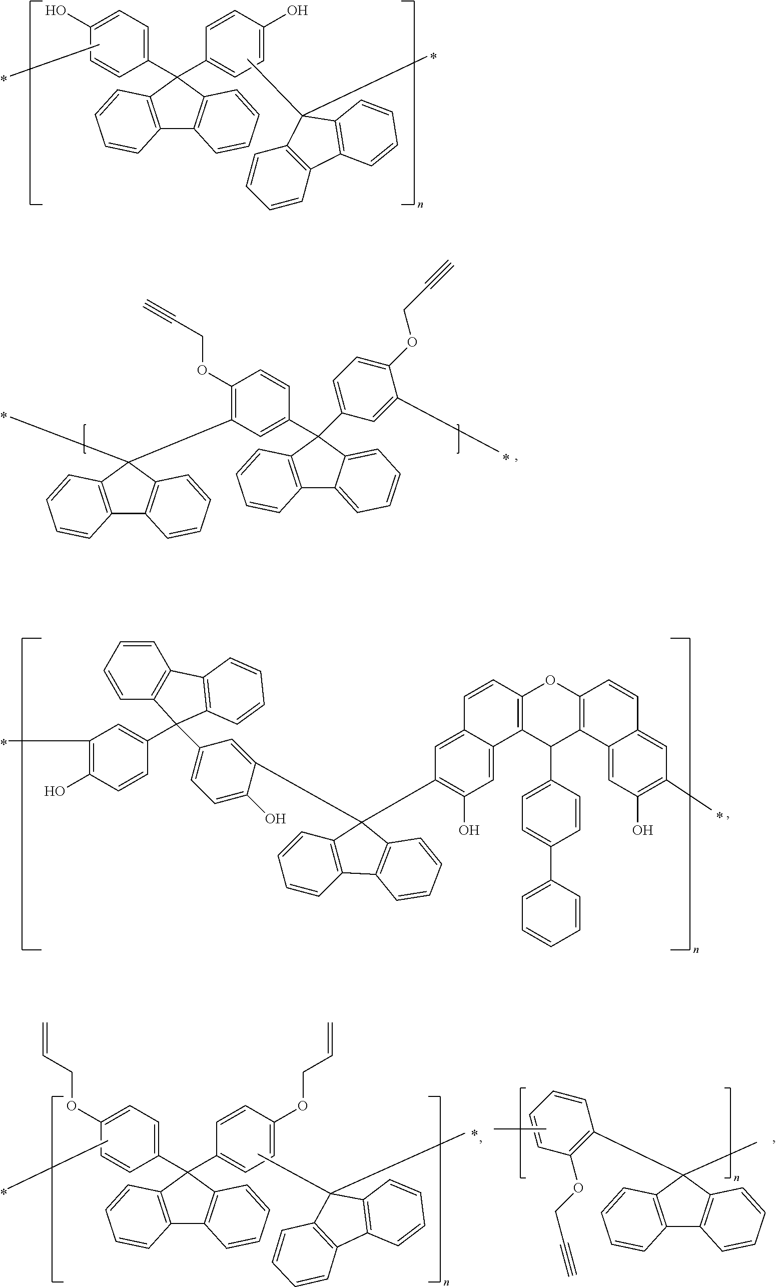

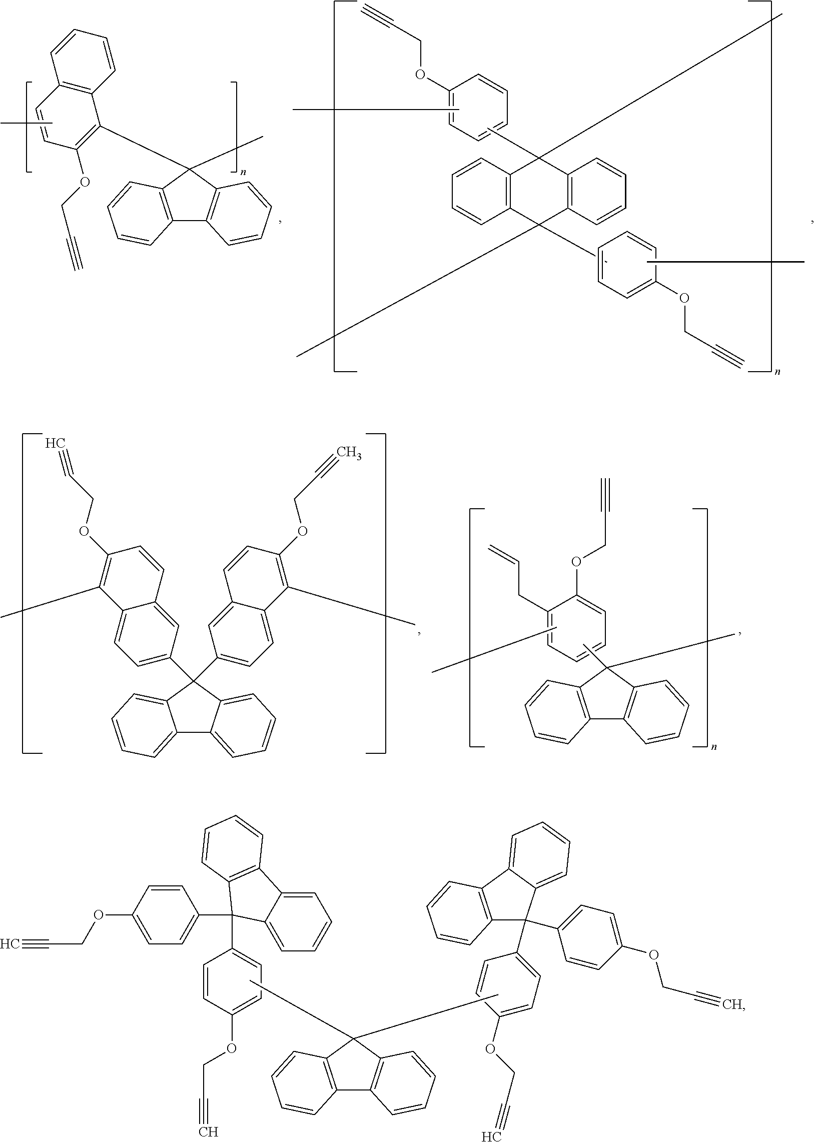

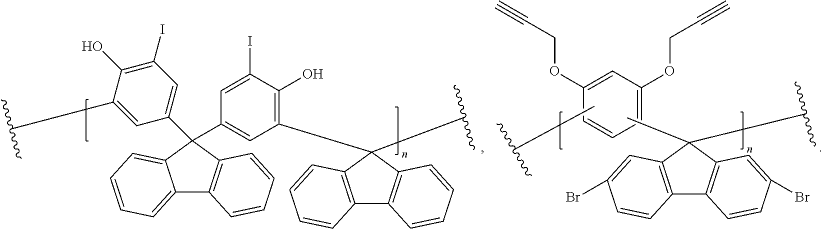

As a more concrete embodiment, unit (A1-1) can be unit (A1-1-1). Unit (A1-1-1) is represented by formula (A1-1-1).

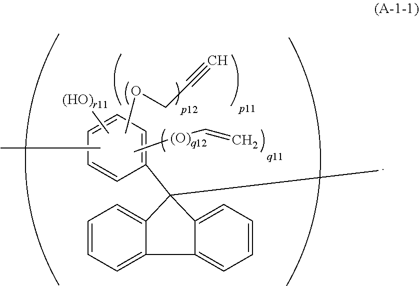

Definitions and/or embodiments of p₁₁, p₁₂, q₁₁, q₁₂ and r₁₁ are each independently the same as described above and p₁₁+q₁₁+r₁₁=1-4.

The unit (A-2) is represented by formula (A-2):

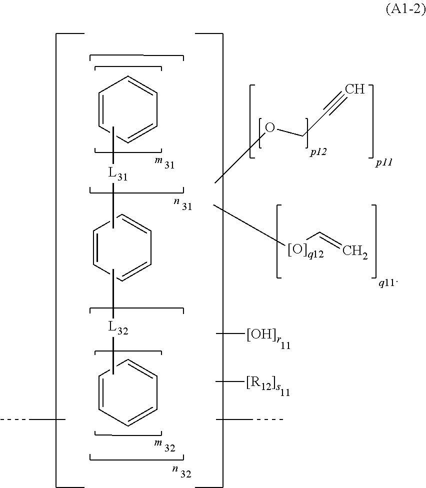

L₃₁ and L₃₂ are each independently a single bond or a phenylene; preferably each are independently a single bond.

n₃₁, n₃₂, m₃₁ and m₃₂ are each independently an integer of 0-6; preferably an integer of 0-3. It is one preferable embodiment of the invention where n₃₁+n₃₂=5 or 6. When L₃₁ is a single bond, m₃₁=1. When L₃₂ is a single bond, m₃₂=1.

Definitions and/or embodiments of R₁₂, p₁₁, p₁₂, q₁₁, q₁₂, r₁₁ and s₁₁ are each independently the same as described above.

Without intending to limit the scope of the invention, exemplified embodiments of the carbon material (A) comprising unit (A1-2) include:

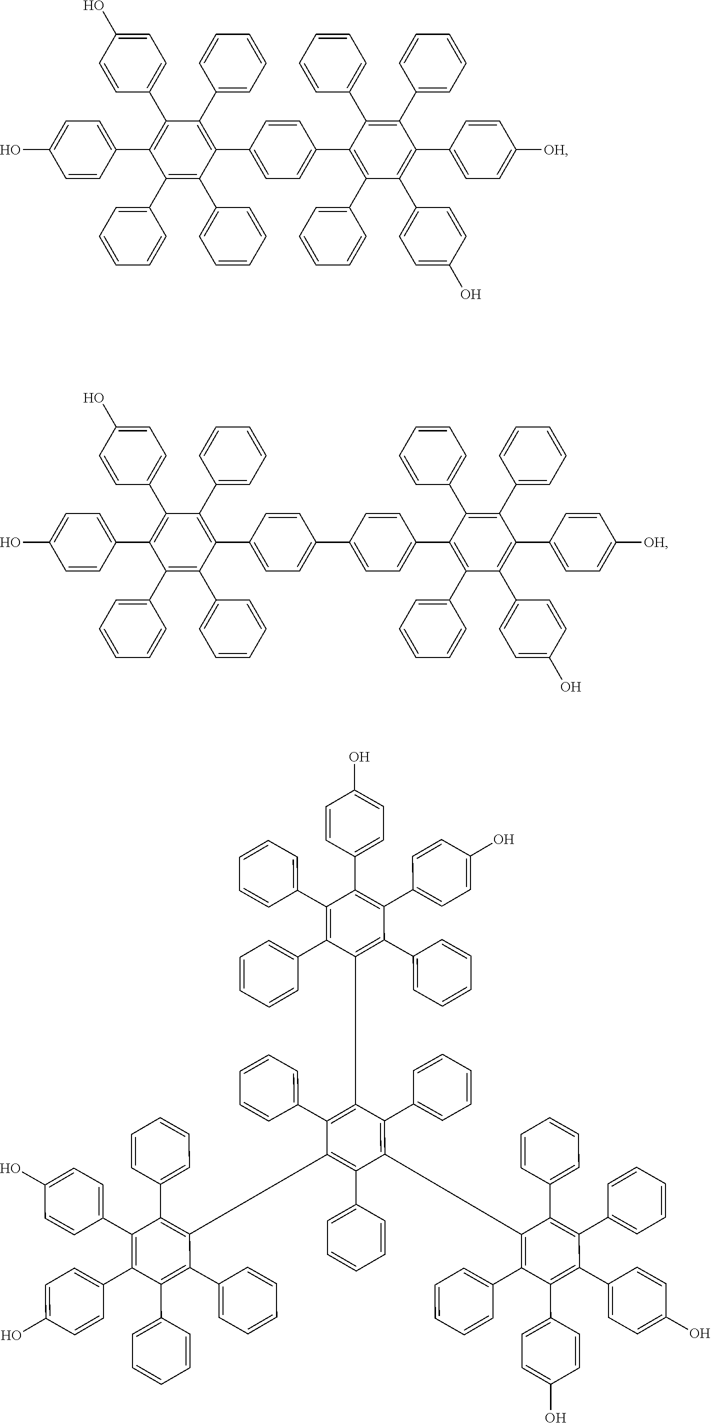

The unit (A-3) is represented by formula (A-3):

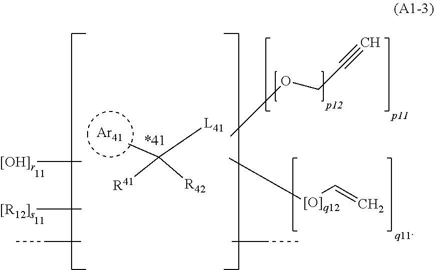

Ar₄₁ is a C₆₋₅₀ aromatic hydrocarbon; preferably Ar₄₁ is phenyl.

R₄₁ and R₄₂ are each independently a C₁₋₁₀ alkyl (preferably a C₁₋₆ linear alkyl). Optionally R₄₁ and R₄₂ can constitute a cyclic hydrocarbon; preferably R₄₁ and R₄₂ constitute a saturated hydrocarbon ring.

The carbon atom at the *41 position is a quaternary carbon atom.

L₄₁ is a C₆₋₅₀ arylene, or a single bond bonding to another unit; preferably phenylene, or a single bond bonding to another unit; more preferably a single bond bonding to another unit.

Definitions and/or embodiments of R₁₂, p₁₁, p₁₂, q₁₁, q₁₂, r₁₁ and s₁₁ are each independently the same as described above.

Without intent to limit the scope of the invention, exemplified embodiments of the carbon material (A) comprising unit (A1-3) include:

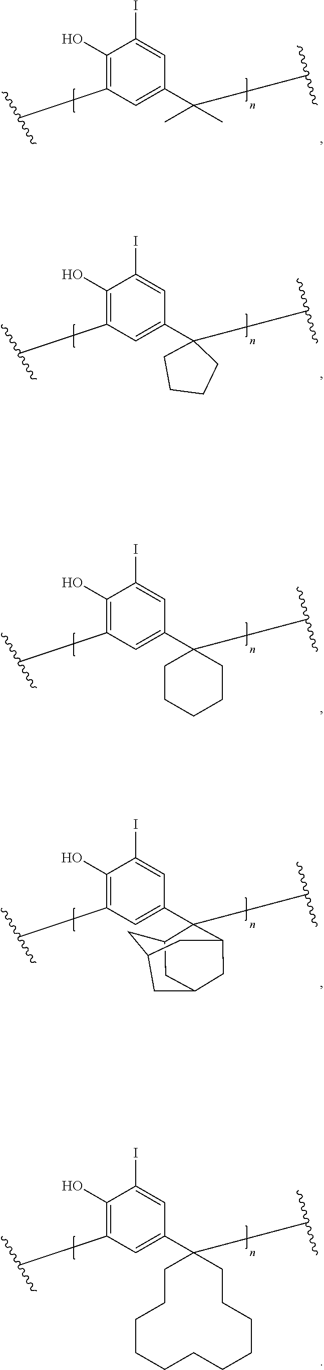

Films made from the composition of this invention possess high heat resistance, when the carbon material (A) is a polymer. In a preferred embodiment thereof, (i) the main chain(s) of the carbon material (A) do not comprise secondary carbon atoms or tertiary carbon atoms or (ii) the sum amount of secondary carbon atoms and tertiary carbon atoms contained in the main chain(s) of the carbon material (A) is low.

In one preferable embodiment of the invention, when the carbon material (A) is a polymer, the amount of the aldehyde derivative used during synthesis of the carbon material (A) is approximately 0 to approximately 30 mol % (more preferably approximately 0 to approximately 15 mol %; further preferably approximately 0 to approximately 5 mol %; further more preferably approximately 0 mol % or 0 mol %), based on all the components to be used for the synthesis. One example of the aldehyde derivative is formaldehyde. In order to obtain a polymer of the carbon material (A) in the main chain of which none or few of secondary carbon atom and tertiary carbon atom is contained, it is one of the preferred embodiments of the present invention to use a ketone derivative.

It is possible the polymer is synthesized such that it contains little or no secondary carbon atoms and/or tertiary carbon atoms. As one preferable embodiment of the invention, when the carbon material (A) is a polymer, the polymer does not comprise secondary carbon atoms or tertiary carbon atoms (other than the terminal(s) of the polymer which can acceptably include a secondary carbon atom and/or a tertiary carbon atom). Not wishing to be bound by theory, it is believed that such a polymer possesses solubility and the formed film possesses improved heat resistance. It is accepted that terminal(s) of the polymer has a secondary carbon atom and/or a tertiary carbon atom.

As one embodiment of the invention, when the carbon material (A) is a polymer, it is preferable that the main chain of the polymer does not comprise an ether linker (—O—) or a sulfone linker (—S(═O)₂—). Here, the term of “linker” means a component which bind units. Terminal modification with such units can be accepted, for example a hydroxyl group. Not wishing to be bound by theory, it is believed that such a polymer exhibits good solubility.

When the carbon material (A) is a polymer, the weight average molecular weight (Mw) is used as its molecular weight.

In the present application, Mw can be measured by gel permeation chromatography (GPC). In a suitable example of this measurement, a GPC column is set to approximately 40° C.; approximately 0.6 mL/min of tetrahydrofuran is used as an elution solvent; and monodisperse polystyrene is used as a standard.

When the carbon material (A) is not a polymer but instead a low molecular weight compound, LC-MASS can be used to measure its molecular weight.

As one aspect of the invention, the molecular weight of the carbon material (A) is approximately 500 to approximately 6,000; preferably approximately 600 to approximately 5,500; more preferably approximately 700 to approximately 5,000; further preferably approximately 800 to approximately 5,000.

The carbon material (A) of the invention may comprise or may not comprise a repeating unit other than unit (A1). In a preferable embodiment the carbon material (A) consists essentially of repeating unit (A1). In another preferable embodiment the carbon material (A) consists of repeating unit (A1). It is one aspect of the invention that the carbon material (A) does not comprise a repeating unit other than the unit (A1).

Carbon Material (A), Unit (A2)

The carbon material (A) of the invention can further comprise unit (A2) and/or unit (A3).

Unit (A2) is represented by formula (A2):

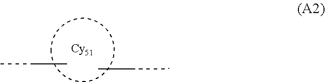

Cy₅₁ is a C₅₋₃₀ cyclic hydrocarbon ring; preferably 9-phenylfluorene, 9,9-diphenylfluorene, adamantane, phenyl, naphthyl, anthracene, phenanthrene, fluoranthene, triphenylene, pyrene, chrysene, or perylene; more preferably fluorene, 9-phenylfluorene, 9,9-diphenylfluorene, or adamantane; further preferably fluorene, or adamantane; further more preferably fluorene.

As one embodiment of the invention, formula (A2) is formula (A2-1):

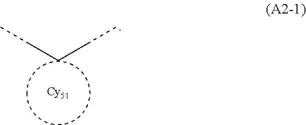

Definitions and/or embodiments of Cy₅₁ are the same as described as above.

Carbon Material (A), Unit (A3)

Unit (A3) is represented by formula (A3):

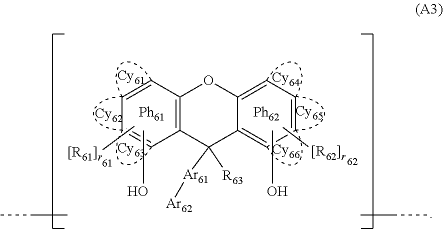

Ar₆₁ is a single bond, C₁₋₆ alkyl, C₆₋₁₂ cycloalkyl, or C₆₋₁₄ aryl; preferably a single bond, C₁₋₆ alkyl, or phenyl; more preferably a single bond, linear C₃ alkyl, linear C₆ alkyl, tertiary butyl, or phenyl; further preferably a single bond or phenyl; further more preferably phenyl.

Ar₆₂ is a C₁₋₆ alkyl, C₆₋₁₂ cycloalkyl, or C₆₋₁₄ aryl; preferably isopropyl, tertiary butyl, C₆ cycloalkyl, phenyl, naphthyl, phenanthryl, or biphenyl; more preferably phenyl.

R₆₁ and R₆₂ are each independently C₁₋₆ alkyl, hydroxy, halogen, or cyano; preferably methyl, ethyl, propyl, isopropyl, tertiary butyl, hydroxy, fluorine, chlorine, or cyano; more preferably methyl, hydroxy, fluorine, or chlorine.

R₆₃ is a hydrogen, C₁₋₆ alkyl, or C₆₋₁₄ aryl; preferably hydrogen, C₁₋₆ alkyl, or phenyl; more preferably hydrogen, methyl, ethyl, linear C₅ alkyl, tertiary butyl, or phenyl; more preferably hydrogen or phenyl; further preferably hydrogen.

When Ar₆₂ is a C₁₋₆ alkyl or C₆₋₁₄ aryl and R₆₃ is a C₁₋₆ alkyl or C₆₋₁₄ aryl, Ar₆₂ and R₆₃ are optionally linked to each other to form a hydrocarbon ring.

r₆₁ and r₆₂ are each independently number of 0-5; preferably 0 or 1; more preferably 0.

At least one of the Cy₆₁, Cy₆₂, and Cy₆₃ rings each surrounded by the broken line is an aromatic hydrocarbon ring fused with the adjacent aromatic hydrocarbon ring Ph₆₁. The total number of carbon atoms of the aromatic hydrocarbon ring and the aromatic hydrocarbon ring Ph₆₁ is preferably C₁₀₋₁₄; more preferably C₁₀.

At least one of the Cy₆₄, Cy₆₅, and Cy₆₆ rings each surrounded by the broken line is an aromatic hydrocarbon ring fused with the adjacent aromatic hydrocarbon ring Ph₆₂. The total number of carbon atoms of the aromatic hydrocarbon ring and the aromatic hydrocarbon ring Ph₆₂ is preferably C₁₀₋₁₄; more preferably C₁₀.

In formula (A3), the bonding positions of R₆₁, R₆₂, and OH are not limited.

For example, the below compound can have a structure of formula (A3) as unit (A3). That is, the aromatic hydrocarbon ring Ph₆₁ and the aromatic hydrocarbon ring Cy₆₃ are fused with each other to form a naphthyl ring (C₁₀), and OH is bonded to the aromatic hydrocarbon ring Cy₆₃. Ar₆₁ is a single bond, Ar₆₂ and R₆₃ are each phenyl, and Ar₆₂ and R₆₃ are linked to each other to form a hydrocarbon ring (fluorene):

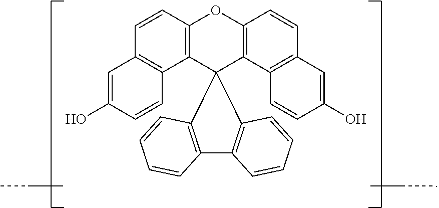

Without intent to limit the scope of the invention, exemplified embodiments of the unit (A3) include:

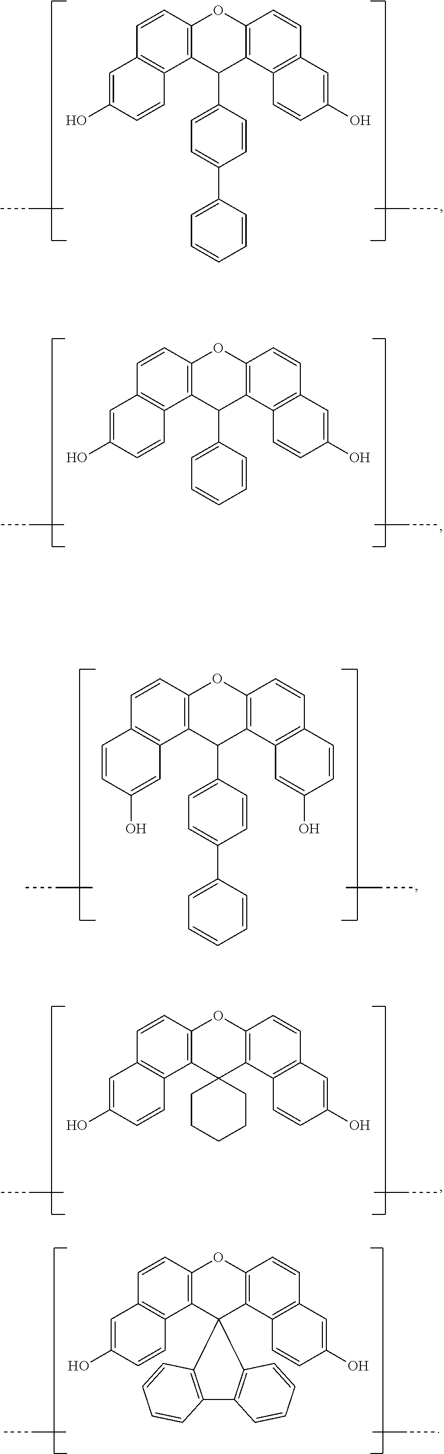

Where carbon material (A) is a polymer, repeating number of unit (A1), unit (A2) and (A3) are each denoted n_{A1}, n_{A2} and n_{A3}, respectively, and n_{A1}>0%.

n_{A1}/(n_{A1}+n_{A2}+n_{A3}) is preferably approximately 1 to approximately 100%; more preferably approximately 10 to approximately 100%; further preferably approximately 20 to approximately 100%; even more preferably approximately 30 to approximately 100%.

n_{A2}/(n_{A1}+n_{A2}+n_{A3}) is preferably approximately 0 to approximately 99%; more preferably approximately 10 to approximately 50%; further preferably approximately 20 to approximately 40%. In one embodiment of the invention n_{A2}/(n_{A1}+n_{A2}+n_{A3})=0%.

n_{A3}/(n_{A1}+n_{A2}+n_{A3}) is preferably approximately 0 to approximately 99%; more preferably approximately 10 to approximately 50%; further preferably approximately 20 to approximately 40%. In one embodiment of the invention n_{A3}/(n_{A1}+n_{A2}+n_{A3})=0%.

Where carbon material (A) is a polymer, nₜₒₜₐₗ denotes total number of repeating therein.

(n_{A1}+n_{A2}+n_{A3})/nₜₒₜₐₗ is preferably approximately 80 to approximately 100%; more preferably approximately 90 to approximately 100%; further preferably approximately 95 to approximately 100%. In one preferable embodiment of the invention (n_{A1}+n_{A2}+n_{A3})/nₜₒₜₐₗ=100%.

For example, the below polymer can be construed as alternating copolymer having unit (A1), unit (A2) and unit (A3) each in this order. In such an embodiment, n_{A1}/(n_{A1}+n_{A2}+n_{A3}), n_{A2}/(n_{A1}+n_{A2}+n_{A3}), n_{A3}/(n_{A1}+n_{A2}+n_{A3})=approximately ⅓ (approximately 33%), and (n_{A1}+n_{A2}+n_{A3})/nₜₒₜₐₗ=100%.

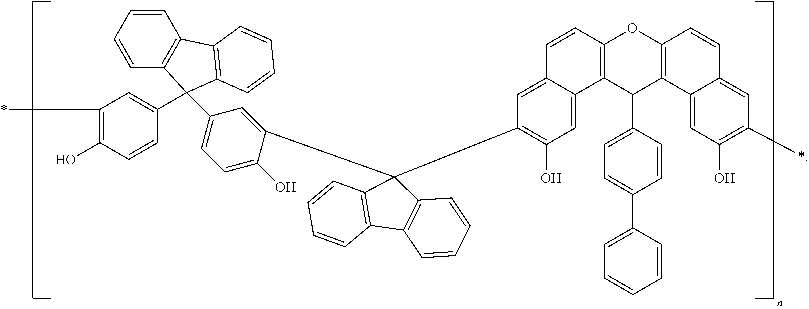

Metal Organic Compound (B)

The spin coating composition of the invention comprises a metal organic compound (B). The metal organic compound (B) is preferably a metal organic complex comprising a hydrolyzable group, a hydrolyzed product of a metal organic complex comprising a hydrolyzable group, a hydrolysis-condensation product of an metal organic complex comprising a hydrolyzable group, or any combination of any of these. As one embodiment of the invention, the metal organic compound (B) is a mixture of plural metal organic compounds having structures represented by (B) for each.

Not wishing to be bound by theory, it is believed that including only metal components in a film is not good because cracking can happen often; the carbon material (A) can be good as a solute because it can avoid making precipitate with metal.

Not wishing to be bound by theory, it is further believed that when the metal oxide film of the invention is made, the carbon components (some or all derived from carbon material (A)) can locate vacant spaces between polymers made from metal organic compound (B); it can make the film density (mass density, more preferably atomic number density) increase; and it can contribute etch resistance.

The metal organic compound (B) can be represented by below formula (B):

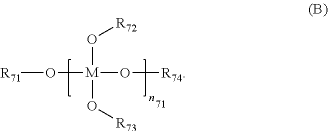

M is a metal having a valence of four (4). Preferably M is at least one selected from the group consisting of Al, Zr, Ta, Hf, Ti, Sn, Pb, Nb, Mo, Ge and W; more preferably Al, Zr, Hf, Ti, Ta, Nb and Sn; further preferably Al, Zr, Hf and Ti; further more preferably A1, Ti and Zr.

n₇₁ is a integer from 1 to 20.

R₇₁, R₇₂, R₇₃ and R₇₄ are each independently selected from the group consisting of a first organic moiety (B)-1, a silicon bearing organic moiety having at least 2 carbons (B)-2, a second organic moiety, and any combination of any of these. Not wishing to be bound by theory, but it is believed that R₇₁ and/or R₇₄ can contribute to the solubility of the metal organic compound (B); and R₇₂ and/or R₇₃ can be cleaved and become further polymerization binding points.

In the formula (B), at least one of the moieties for R₇₁, R₇₂, R₇₃ and R₇₄ is selected from the group consisting of:

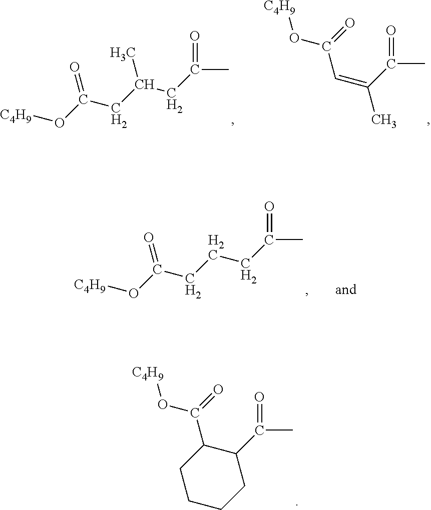

The first organic moiety (B)-1 is represented by formula (B)-1:

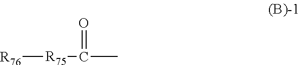

R₇₅ is selected from the group consisting of a C₂₋₁₀ alkylene, C₃₋₁₂ branched alkylene, C₅₋₁₂ cycloalkylene, C₂₋₁₀ alkylene containing a C═C double bond, C₃₋₁₂ branched alkylene containing a C═C double bond, and C₅₋₁₂ cycloalkylene containing a C═C double bond; preferably C₂₋₁₀ alkylenes, C₂₋₁₀ alkylenes containing a C═C double bond, and C₅₋₁₂ cycloalkylene; more preferably a C₂₋₁₀ alkylene. In another embodiment of the invention R₇₅ is a C₂₋₁₀ alkylene containing a C═C double bond. In another aspect of the invention R₇₅ is a C₅₋₁₂ cycloalkylene.

R₇₆ is a hydrogen or an alkyloxycarbonyl represented by a formula (B)-1-1.

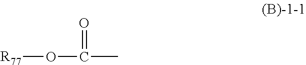

As one embodiment of the invention, the alkyloxycarbonyl of R₇₆ is preferably a C₁₋₈ alkyloxycarbonyl; more preferably a C₂₋₆ alkyloxycarbonyl; further preferably a C₃₋₄ alkyloxycarbonyl.

R₇₇ is a C₁₋₈ alkyl; preferably a C₂₋₆ alkyl; preferably a C₃₋₄ alkyl.

The silicon bearing organic moiety having at least 2 carbons (B)-2 is represented by formula (B)-2:

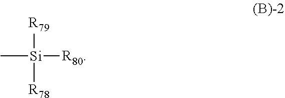

R₇₈ and R₇₉ are each independently selected from the group consisting of a C₁₋₈ alkyl, C₃₋₁₂ branched alkyl, C₁₋₈ alkyloxy, C₃₋₁₂ branched alkyloxy, and C₆₋₁₆ aryl; preferably methyl, ethyl, propyl, butyl and t-butyl. In another embodiment of the invention, it is preferable that R₇₈ and R₇₉ are each independently a C₁₋₈ alkyloxy, C₃₋₁₂ branched alkyloxy, or C₆₋₁₆ aryl.

R₈₀ is selected from the group consisting of a C₁₋₈ alkyl, C₆₋₁₆ aryl, hydroxyl and siloxane having the structure (B)-2-1; preferably methyl, ethyl, propyl, butyl, t-butyl, and siloxane having the structure (B)-2-1; more preferably methyl, and siloxane having the structure (B)-2-1; further preferably methyl:

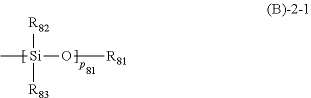

R₈₁ is selected from the group consisting of a hydrogen, C₁₋₈ alkyl, C₁₋₈ alkyl substituted with a hydroxyl, a C₆₋₁₆ aryl, and a silyl moiety having structure (B)-2-1-1; preferably hydrogen, C₁₋₈ alkyl and a silyl moiety having structure (B)-2-1-1; more preferably hydrogen, C₁₋₄ alkyl and a silyl moiety having structure (B)-2-1-1; further more preferably hydrogen, and a silyl moiety having structure (B)-2-1-1. It is also one aspect of the invention that R₈₁ is selected from the group consisting of a C₁₋₄ alkyl and a silyl moiety having structure (B)-2-1-1. It is another embodiment of the invention that R₈₁ is a methyl or t-butyl; preferably methyl:

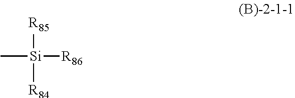

R₈₄ and R₈₅ are each independently selected from the group consisting of a C₁₋₈ alkyl, C₃₋₁₂ branched alkyl, C₁₋₈ alkyloxy, C₃₋₁₂ branched alkyloxy, and C₆₋₁₆ aryl; preferably methyl, ethyl, propyl, butyl, t-butyl, methoxy, and phenyl; more preferably methyl, t-butyl and phenyl; further preferably methyl.

R₈₆ is selected from the group consisting of a C₁₋₈ alkyl, and C₆₋₁₆ aryl; preferably methyl, ethyl, propyl, butyl, t-butyl, and phenyl; more preferably methyl, t-butyl and phenyl; further preferably methyl.

p₈₁ represents the number of repeat units in the siloxane moiety (B)-2-1. As one embodiment of the invention, p₈₁=1-500; preferably 1-200; more preferably 1-50.

R₈₂ and R₈₃ are each independently selected from the group consisting of a C₁₋₈ alkyl, C₃₋₁₂ branched alkyl, C₁₋₈ alkyloxy, C₃₋₁₂ branched alkyloxy, and C₆₋₁₆ aryl; preferably methyl, ethyl, propyl, butyl, t-butyl, and phenyl; more preferably methyl, t-butyl and phenyl; further preferably methyl.

The second organic moiety is selected from the group consisting of a C₂₋₈ alkyl, C₂₋₈ alkyl carboxyl, C₆₋₂₀ aryl carboxyl, fluorenyl carboxyl, fluorinated C₂₋₈ alkyl carboxyl, C₂₋₈ alkyl sulfonyl, fluorinated C₂₋₈ alkyl sulfonyl, and any combination of these.

Without intent to limit the scope of the invention, exemplified embodiments of the metal organic compound (B) include:

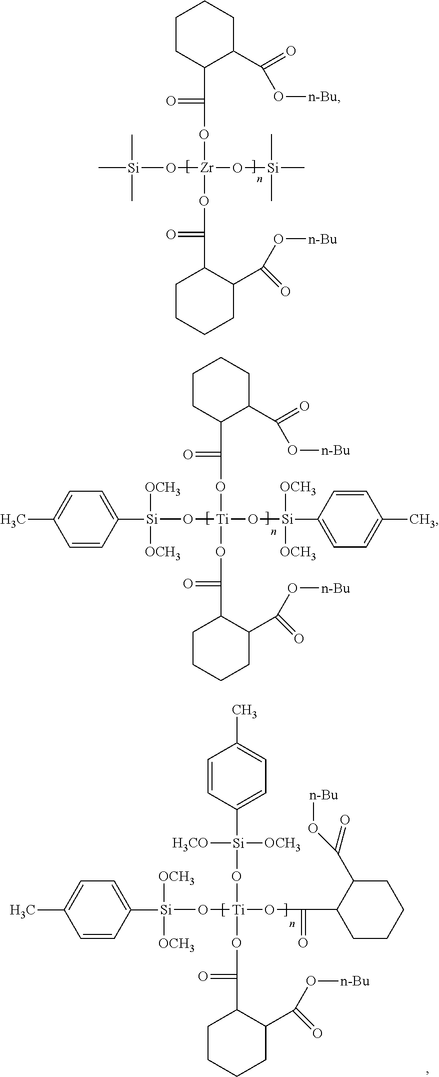

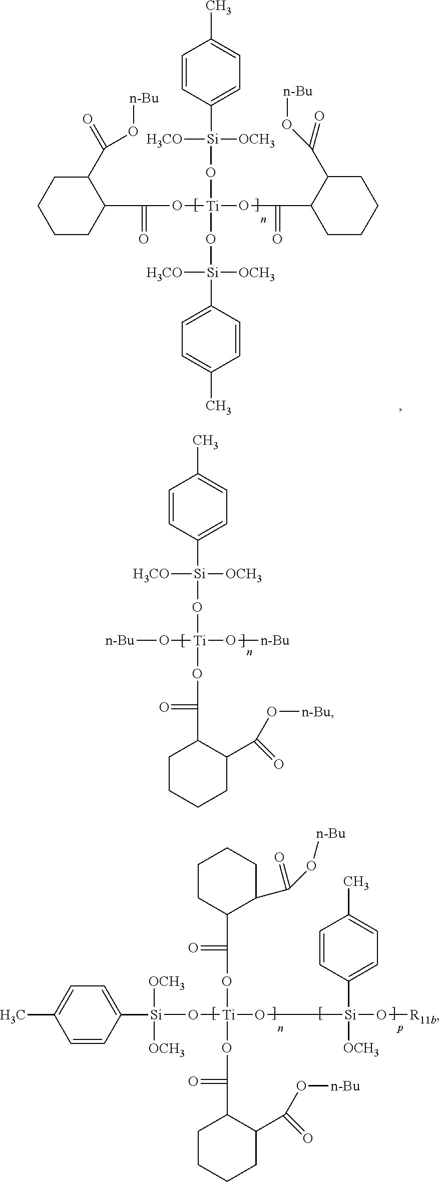

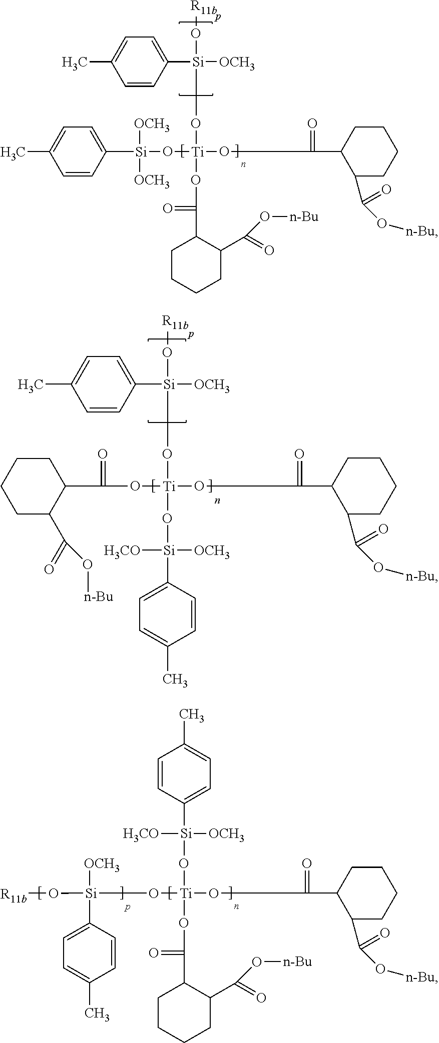

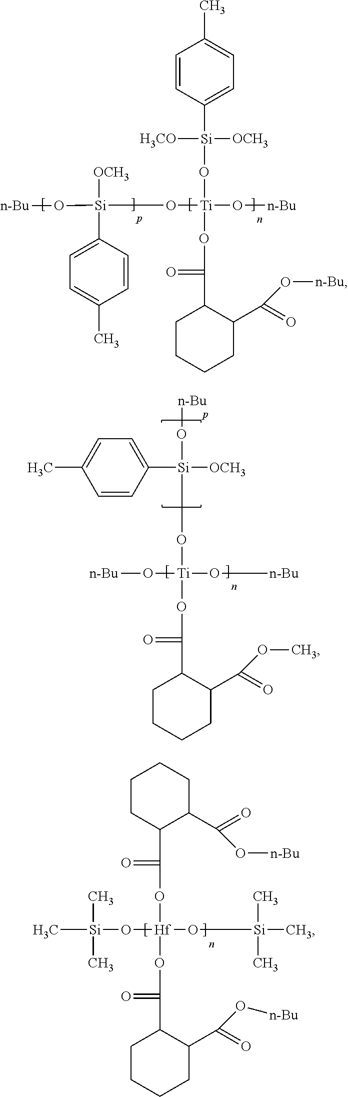

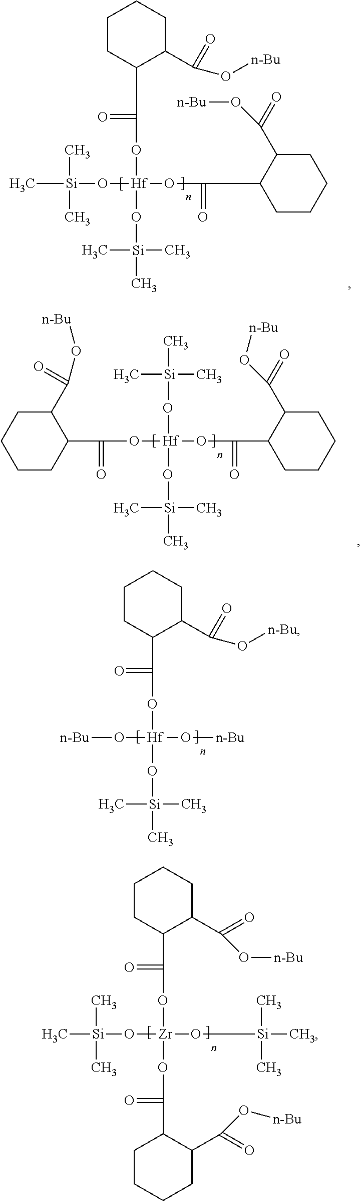

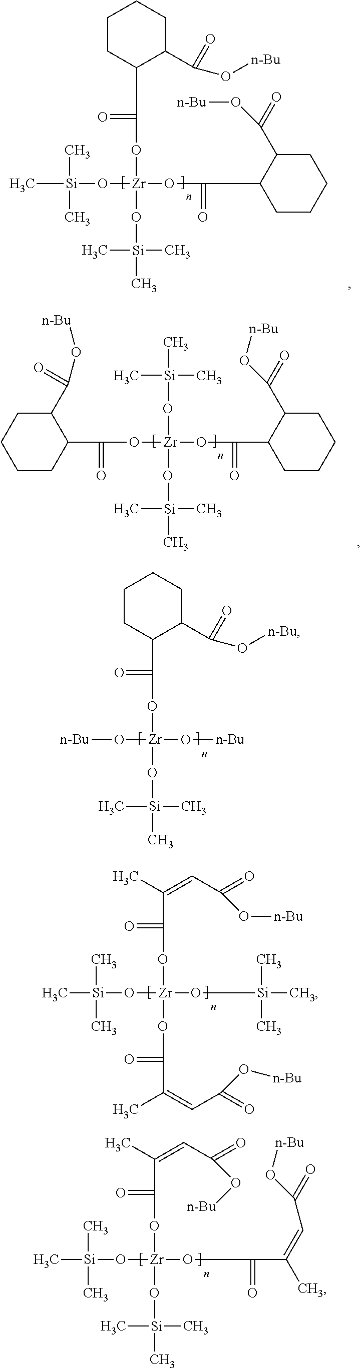

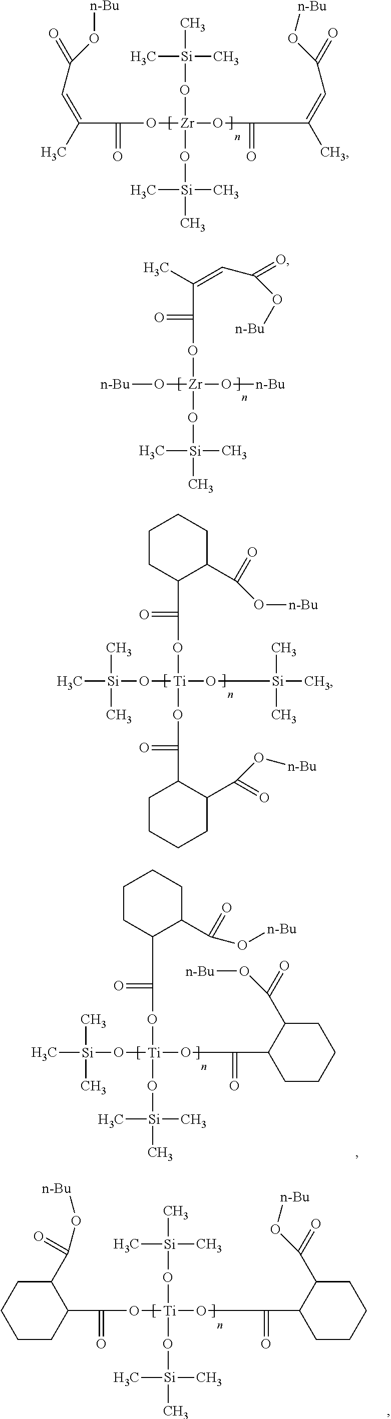

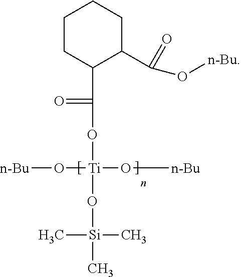

In one embodiment of the invention, the mass ratio of the metal organic compound (B) to the total mass of the spin coating composition is approximately 5 to approximately 100 mass %; preferably approximately 10 to approximately 75 mass %; more preferably approximately 10 to approximately 50 mass %.

Solvent (C)

The spin coating composition of this invention comprises solvent (C), and the solvent (C) comprises an organic solvent. The solvent (C) cannot consist exclusively of an inorganic solvent, e.g., water.

It is preferable embodiment of this invention that solvent (C) is selected from the group consisting of an aliphatic hydrocarbon solvent, aromatic hydrocarbon solvent, monoalcohol solvent, polyol solvent, ketone solvent, ether solvent, ester solvent, nitrogen-containing solvent, sulfur-containing solvent, and any combination of any of these.

Examples of the solvent (C)s include: aliphatic hydrocarbon solvents such as n-pentane, i-pentane, n-hexane, i-hexane, n-heptane, i-heptane, cyclohexane, and methylcyclohexane; aromatic hydrocarbon solvents such as benzene, toluene, xylene, ethylbenzene, trimethylbenzene, methylethylbenzene, n-propylbenzene, i-propylbenzene, diethylbenzene, and i-butylbenzene, monoalcohol solvents such as methanol, ethanol, n-propanol, i-propanol, n-butanol, i-butanol, sec-butanol, t-butanol, n-pentanol, i-pentanol, 2-methylbutanol, 2-ethylhexanol, n-nonyl alcohol, 2,6-dimethylheptanol-4, n-decanol, cyclohexanol, benzyl alcohol, phenylmethylcarbinol, diacetone alcohol, and cresol; polyol solvents such as ethylene glycol, propylene glycol, 1,3-butylene glycol, diethylene glycol, dipropylene glycol, triethylene glycol, tripropylene glycol, and glycerin; ketone solvents such as acetone, methyl ethyl ketone, methyl n-propyl ketone, methyl n-butyl ketone, diethyl ketone, trimethylnonanone, cyclohexanone, cyclopentanone, methylcyclohexanone, 2,4-pentanedione, acetonylacetone, acetophenone, and fenchone; ether solvents such as ethyl ether, i-propyl ether, n-butyl ether, n-hexyl ether, 2-ethylhexyl ether, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents such as diethyl carbonate, methyl acetate, ethyl acetate, γ-butyrolactone, γ-valerolactone, n-propyl acetate, i-propyl acetate, n-butyl acetate, i-butyl acetate, n-butyl propionate, methyl lactate, ethyl lactate (EL), γ-butyrolactone, n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, and propylene glycol monopropyl ether acetate; nitrogen-containing solvents such as N-methylformamide; and sulfur-containing solvents such as dimethyl sulfide. Any combination of any of these solvents can also be used.

In particular, cyclohexanone, cyclopentanone, PGME, propylene glycol monoethyl ether, propylene glycol monopropyl ether, propylene glycol monobutyl ether, propylene glycol dimethyl ether, propylene glycol diethyl ether, PGMEA, propylene glycol monoethyl ether acetate, propylene glycol monopropyl ether acetate, γ-butyrolactone, EL, and any combination of any of these are preferred in terms of the storage stability of the solution.

In terms of the coatability and/or solubility of the solute, PGME, PGMEA, EL, and a combination of any two solvents selected therefrom are preferred. For this purpose, combination of PGMEA and PGME is more preferable as solvent (C).

When solvent (C) is 2 organic solvents combination, the mass ratio of the 1^{st} solvent and 2^{nd} solvent is preferably approximately 95:5 to approximately 5:95; more preferably approximately 90:10 to approximately 10:90; further preferably approximately 80:20 to approximately 20:80; even more preferably approximately 70:30 to approximately 30:70.

The amount of water in the solvent (C) is preferably 0.1 mass % or less and further preferably approximately 0.01 mass % or less. Given the relationship with another layer or coating, it is preferable for the solvent (C) to be free of water. As one aspect of the invention, the amount of water in the solvent (C) is preferably 0.00 mass %.

As one embodiment of the invention, the mass ratio of the solvent (C) to the total mass of the spin coating composition is approximately 5 to approximately 100 mass %; preferably approximately 10 to approximately 75 mass %; more preferably approximately 10 to approximately 50 mass %.

Surfactant (D)

The spin coating composition of the invention can comprise a surfactant (D), which is useful for decreasing pin hole or striation in a coating, and for increasing coatability and/or solubility of a composition.

In one embodiment of the invention the mass ratio of the surfactant (D) to the mass of the metal organic compound (B) is approximately 5 to approximately 100 mass %; preferably approximately 10 to approximately 75 mass %; more preferably approximately 10 to approximately 50 mass %.

Examples of the surfactant include: polyoxyethylene alkyl ether compounds such as polyoxyethylene lauryl ether, polyoxyethylene stearyl ether, and polyoxyethylene oleyl ether; polyoxyethylene alkylaryl ether compounds such as polyoxyethylene octylphenol ether and polyoxyethylene nonylphenol ether; polyoxyethylene-polyoxypropylene block copolymer compounds; sorbitan fatty acid ester compounds such as sorbitan monolaurate, sorbitan monopalmitate, sorbitan monostearate, sorbitan trioleate, and sorbitan tristearate; and polyoxyethylene sorbitan fatty acid ester compounds such as polyoxyethylene sorbitan monolaurate, polyoxyethylene sorbitan monopalmitate, polyoxyethylene sorbitan monostearate, and polyoxyethylene sorbitan tristearate. Other examples of the surfactant include: fluorosurfactants such as EFTOP (trade name) EF301, EF303, and EF352 (Tohkem Products), MEGAFACE (trade name) F171, F173, R-08, R-30, R-41 and R-2011 (DIC), Fluorad FC430 and FC431 (Sumitomo 3M), AsahiGuard (trade name) AG710 (Asahi Glass), and SURFLON S-382, SC101, SC102, SC103, SC104, SC105, and SC106 (Asahi Glass); and organosiloxane polymers such as KP341 (Shin-Etsu Chemical).

Additive (E)

The spin coating composition of this invention can further comprise additive (E) other than surfactant (D). Such an additive can be selected from the group consisting of a cross linker, acid generator, radical generator, photo polymerization initiator, an agent for enhancing adhesion to substrates, and an anti-foaming agent.

In one aspect of the invention, the mass ratio of other additives (E) to the mass of the metal organic compound (B) is preferably approximately 0.05 to approximately 10 mass %; more preferably approximately 0.10 to approximately 5 mass %; further preferably approximately 0.10 to approximately 2 mass %. In one embodiment of the invention the spin coating composition contains none (0 mass %) of these additives (E).

Formation of Metal Oxide Film

This invention provides a method of manufacturing a metal oxide film comprising (1) spin coating the spin coating composition described above a substrate; and (2) heating said spin coating composition to make a metal oxide film.

Although describing for clarity, the numbers in brackets reflect the order of steps. For example, the step (1) is performed before the step (2). This convention holds for other described steps herein unless otherwise specifically stated.

Preferably the heating condition is approximately 150 to approximately 400° C. and/or approximately 30 to approximately 120 seconds. The term “above a substrate” may denote that the applied spin coating composition can form coating directly on the substrate (i.e., in direct contact with the substrate), but also include that an underlayer may be interposed between the substrate and the applied composition. The term “above” comprises “direct contact with” and “intervening layer hereinafter, otherwise specifically stated.

The substrate surface on which the composition is disposed can be pre-treated, for example by 1,1,1,3,3,3-hexamethyldisilazane solution. The upper surface of the substrate can be flat or not-flat. The substrate can be a patterned substrate or an unpatterned substrate. The substrate may be a single-layer substrate, or a multi-layer substrate composed of a plurality of substrate layers. In one embodiment of the invention, the upper most surface of the substrate is a patterned semiconductor. The semiconductor may be composed of oxide, nitride, metal, and any combination of any of these. The surface of the substrate is preferably selected from the group consisting of Si, Ge, SiGe, Si₃N₄, TaN, SiO₂, TiO₂, Al₂O₃, SiON, HfO₂, T₂O₅, HfSiO₄, Y₂O₃, GaN, TiN, TaN, Si₃N₄, NbN, Cu, Ta, W, Hf, and Al.

By virtue of the refractory nature of the content of metal organic compound (B) in the composition of the invention, the formed metal oxide film possesses good etch resistance to various plasmas and allows a pattern to be etched and transferred into the substrate.

The spin coating composition is applied by an appropriate application means such as a spin-coater or coater.

It is one aspect of the invention the heating condition is selected from the range of approximately 200 to approximately 800° C. (preferably approximately 250 to approximately 750° C., more preferably approximately 300 to approximately 700° C., further preferably approximately 350 to approximately 650° C., further more preferably approximately 400 to approximately 600° C.), and/or the heating time is selected from the range of approximately 30 to approximately 240 seconds (preferably approximately 40 to approximately 150 seconds, more preferably approximately 50 to approximately 120 seconds, further more preferably approximately 60 to approximately 90 seconds). The heating can be carried out in separate steps (step baking). For example, the heating may be two-step heating or three-step heating. For example, it is preferable that the first heating be performed at approximately 200 to approximately 300° C. for approximately 30 to approximately 120 seconds, and the second heating be performed at approximately 300 to approximately 500° C. for approximately 60 to approximately 180 seconds.

The heating may be performed in an air atmosphere, whose oxygen concentration can be reduced to prevent oxidation of the spin coating composition and the formed metal oxide film. For example, the oxygen concentration may be adjusted to approximately 1,000 ppm or less (preferably approximately 100 ppm or less) by introducing an inert gas (N₂, Ar, He, or a mixture thereof) into the atmosphere. Changing atmospheres in plural heating step is possible. It is one embodiment of the invention that the heating is performed in N₂ atmosphere.

In one embodiment of the invention the spin coating composition is applied to an underlayer (e.g., spin on carbon layer, planarization layer) or a substrate comprising topographical features. As embodiments of the invention, the formed metal oxide film has a thickness sufficient to overlay said topographical features; and a chemical stripper or a fluorinated plasma etch can be used to produce filled topographical features wherein the metal oxide film is flush with the top of said topographical features. Said topographical features can have an aspect ratio of approximately 1 to approximately 10 and/or critical dimension (CD) from approximately 5 nm to approximately 100 nm.

In a preferable embodiment of the invention the metal content of the metal oxide film is approximately 5 to approximately 85 mass % (more preferably approximately 10 to approximately 50 mass %; further preferably approximately 15 to approximately 40 mass %) to the total mass of the film. The metal content in the metal oxide film can be measured by Rutherford Backscattering Spectrometry/Hydrogen Forward Scattering (RBS/HFS).

Formation of Resist Layer

This invention further provides a method of manufacturing a resist coating comprising (3) applying a resist composition above the metal oxide film manufactured by above method. The term “above the metal oxide film” may denote that the applied resist composition can form resist coating directly on the metal oxide film (i.e., in direct contact with the metal oxide film), but also includes that an interlayer (e.g., bottom antireflective coating, BARC) may be interposed between the metal oxide film and the applied resist composition. The interlayer may include a single of layer or a plurality of layers. Other layer(s) (e.g., a top anti-reflective coating, TARC) may be formed on the resist coating.

A known method can be used for the application such as spin coating. The applied resist composition can be baked to remove the solvent in the composition, thereby forming a resist coating. The baking temperature can vary depending on the resist composition to be used, which is preferably approximately 70 to approximately 150° C. (more preferably approximately 90 to approximately 150° C., further preferably approximately 100 to approximately 140° C.). It can be carried out for approximately 10 to approximately 180 seconds, preferably for approximately 30 to approximately 90 seconds in the case of on a hot plate, or for approximately 1 to approximately 30 minutes in case of in a hot gas atmosphere (for example in a clean oven). The formed resist coating can have a thickness of approximately 0.40 to approximately 5.00 μm preferably (approximately 0.40 to approximately 3.00 μm more preferably, approximately 0.50 to approximately 2.00 μm further preferably).

Formation of Resist Patterns

This invention provides a method of manufacturing resist patterns comprising (4) exposing the resist coating manufactured by above method(s) by radiation light; (5) developing the exposed resist coating by developer; and (6) removing the developer from the substrate.

The resist composition undergoes a reaction under irradiation through certain masks. Preferably in ArF exposure, immersion lithography technique can be used. In the case the resist composition is positive tone, irradiated portions increase resistance against dissolution by a developer. The wavelength of the radiation light used for exposure is not limited. The exposure is preferably performed with light having a wavelength of approximately 13.5 to approximately 365 nm (preferably approximately 13.5 to approximately 248 nm). KrF excimer laser (248 nm), ArF excimer laser (193 nm), or extreme ultraviolet light (13.5 nm) are preferred embodiments; KrF excimer laser is more preferred. It is also another preferable embodiment of this invention that this composition is used in the process using EUV or immersion ArF. These wavelengths may vary within ±1%.

The exposure can, if desired, be followed by a post-exposure bake (PEB). The temperature for the PEB is selected from the range of approximately 80 to approximately 150° C. (preferably approximately 90 to approximately 140° C.), and the heating time for the PEB is selected from the range of approximately 0.3 to approximately 5 minutes (preferably approximately 0.5 to approximately 2 minutes).

Next, development is performed with a developer. An approximately 2.38 mass % (±1% concentration change accepted) aqueous TMAH solution is preferred as the developer used for the development in the resist patterns formation. An additive such as a surfactant can be added to the developer. The temperature of the developer is typically selected from the range of approximately 5 to approximately 50° C. (preferably approximately 25 to approximately 40° C.), and the development time is typically selected from the range of approximately 10 to approximately 300 seconds (preferably approximately 30 to approximately 90 seconds). As the developing method, known methods such as paddle development can be used.

After development, the developer can be removed by known methods (e.g., replacing liquid or spin dry). As one embodiment of the invention, the resist patterns can be cleaned by water or cleaning solution as replacing developer with the water and/or cleaning solution. Then, the substrate can be dried, for example by a spin dry method.

Processing Substrate

The invention provides a method of manufacturing processed substrates comprising (7) etching with the resist patterns manufactured by above method(s) and (8) processing the substrate.

As described above, there can be underlayers and/or interlayers in the multi-layer configurations manufactured. The left-to-right direction in the following list corresponds to the bottom-to-top direction in the multi-layer configurations (including resist patterns):
i. Substrate/underlayer/metal oxide film/interlayer/resist patterns;
ii. Substrate/metal oxide film/interlayer/resist patterns;
iii. Substrate/metal oxide film/resist patterns; and/or
iv. Substrate/underlayer/metal oxide film/resist patterns.

Layers and/or metal oxide film below resist patterns can be patterned through the resist patterns as a mask. For the pattern formation, known techniques such as etching (dry etching) can be used.

For example, the interlayer may be etched through the resist pattern as an etching mask, and then the metal oxide film of the invention and substrate may be etched through the resulting interlayer pattern as an etching mask to form a pattern on the substrate. Alternatively, the mask oxide film may be etched through the resist pattern or interlayer pattern as an etching mask to obtain metal oxide film patterns. Then, the underlayer may be etched through the resulting metal oxide film patterns as an etching mask, and then the substrate may be etched through the resulting underlayer patterns as an etching mask to form a pattern on the substrate.

As one embodiment, dry etching can be conducted with O₂, CF₄, CHF₃, Cl₂, or BCl₃. O₂ or CF₄ are preferable gases for an organic coating/layer.

In one embodiment, RF discharge power of approximately 100 to approximately 10,000 W (more preferably approximately 200 to approximately 5,000 W) and/or in the gas atmosphere of N₂, NF₃, O₂ rare gas, Cl₂, HBr, or any mixture of any of them can be used to etch a metal oxide film to obtain a metal oxide film.

One method of the invention to process a substrate is described below:
i. Forming metal oxide film as described above,
ii. Coating a BARC on the metal oxide film,
iii. Appling a resist composition on the BARC,
iv. Forming resist patterns as described above,
v. Etching through said BARC not protected by said resist patterns down to the metal oxide film with a fluorinated plasma,
vi. Etching through said metal oxide film not protected by the BARC and said resist pattern down to the substrate with a chlorine plasma producing a patterned metal oxide film,
vii. Etching with a fluorinated plasma into the substrate in those area not protected by said patterned metal oxide film.

After the substrate is processed, patterns and/or layers on/above it can be removed by known method.

Device Manufacturing

This invention provides a method of manufacturing a device comprising the manufacturing method of processed substrate described above. Preferably the method of manufacturing a device further comprise (9) forming wiring in the processed substrate.

Preferably the substrate(s) is a stepped substrate.

After formation of the device, the substrate, if necessary, is cut into chips, which are connected to a lead frame and packaged with a resin. Preferably the device is a semiconductor device, solar cell chip, organic light emitting diode and inorganic light emitting diode. One preferable embodiment of the device of this invention is a semiconductor device.

### EXAMPLES

Hereinafter, the present invention will be described with working examples. These examples are given only for illustrative purpose and not intended to limit the scope of the present invention.

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Preparation Example 1 of Working Example Composition 1

Components A1 (2.0 mass %), B1 (7.9 mass %)

| | | |
|---|---|---|
| A1 | 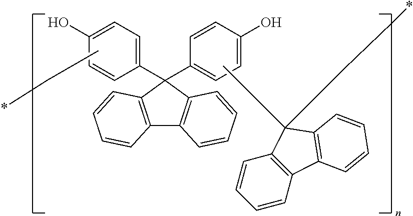 | Mn = 533 Da, Mw = 674 Da, Mw/Mn = 1.26 |
| B1 | 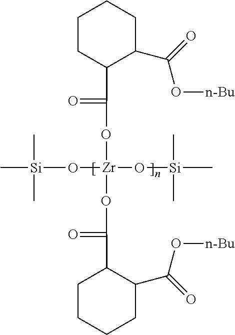 | — |

and surfactant Megaface® R-41 (0.1 mass %, DIC) are added into the solvent which is mixture of PGMEA (63 mass %) and PGME (27 mass %). The liquid is mixed with a stirrer for 10 minutes at room temperature. It is visually confirmed all solutes are dissolved. Resultant liquid is filtrated by 0.2 micrometer fluorinated resin filter to obtain Working Example Composition 1.

The polymer used is obtained in the same manner described in WO2019/121480 A1, JP2019-86545A and WO2019/048393A1.

### Preparation Example 2-4 of Working Example Composition 2-4 and Comparative Preparation Example 1-2 of Comparative Example Composition 1-2

Preparations are carried out in the same manner as in Preparation Example 1 above except for changing the components (using components A2, A3, A4 and cA1) and/or the amounts as described in Table 1:

| | | |
|---|---|---|
| A2 | 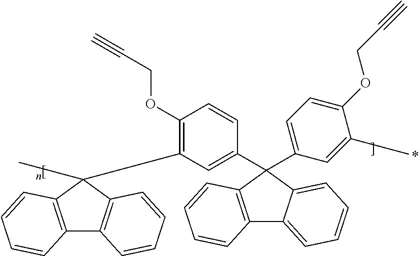 [SMILES: *Cc1cc(C2(c3ccc(OCC#C)c(CCC4(CC)c5ccccc5-c5ccccc54)c3)c3ccccc3-c3ccccc32)ccc1OCC#C] | Mn = 789 Da, Mw = 1,054 Da, Mw/Mn = 1.34 |
| A3 | 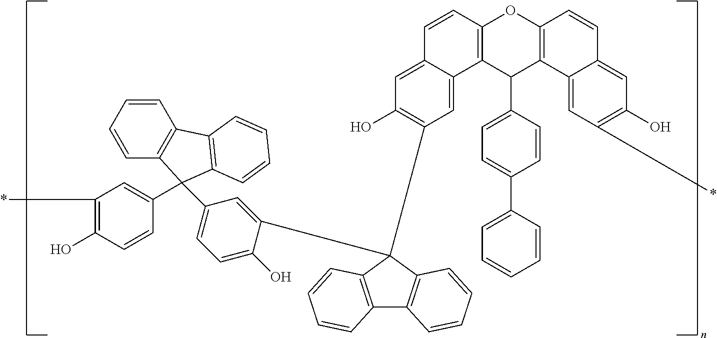 | Mn = 1,430 Da, Mw = 2,488 Da, Mw/Mn = 1.74 |
| A4 | 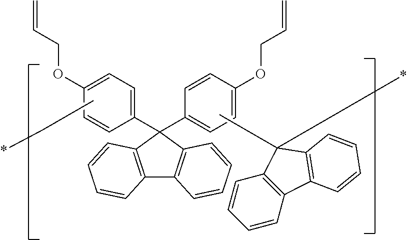 | Mn = 671 Da, Mw = 833 Da, Mw/Mn = 1.32 |
| cA1 | 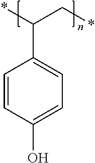 | Mn = 4,998 Da, Mw = 4,388 Da, Mw/Mn = 1.14 |

It is visually confirmed that all solutes in each composition are dissolved. Resultant liquids are filtrated by 0.2 micrometer fluorinated resin filter to obtain Working Example Compositions 2-4 and Comparative Example Compositions 1-2.

The resulting compositions have the following characteristics:

TABLE 1

| | Carbon | Metal Organic |
|---|---|---|
| | Material (A) | Compound (B) |
| Working Ex. Composition 1 | A1(2.0) | M1(7.9) |
| Working Ex. Composition 2 | A2(2.0) | M1(7.9) |
| Working Ex. Composition 3 | A3(2.0) | M1(7.9) |
| Working Ex. Composition 4 | A4(2.0) | M1(7.9) |
| Comparative Ex. Composition 1 | — | M1(9.9) |
| Comparative Ex. Composition 2 | cA1(2.0) | M1(7.9) |

In Table 1 and subsequent tables, numbers in brackets means the amount by mass % of each component in the composition.

### Metal Oxide Film Formation Example 1 of Working Example Composition 1

Working Example Composition 1 is spin coated on a Si bare wafer at 1,500 rpm with CLEAN TRACK ACT 12 (Tokyo Electron). This wafer is baked at 250° C. for 60 second in air atmosphere, and then further baked at 400° C. for 120 second in N₂ atmosphere to obtain the metal oxide film.

### Metal Oxide Film Formation Example of Working Example Composition 2-4 and Comparative Preparation Example 1-2 of Comparative Example Composition 1-2

Formations are carried out in the same manners as in metal oxide film formation example 1, except for changing the working example composition or comparative example composition.

Evaluation of Solubility

The solubility of each composition is evaluated by visual confirmation. The evaluation results are shown in Table 2. In Table 2, “A” means that the solutes in the composition are dissolved completely; “B” means that the solutes in the composition are not completely dissolved and remain in the solvent.

Evaluation of Cracking

The existence of cracking on the surface of the metal oxide film made from each composition is evaluated by visual confirmation. The evaluation results are shown in Table 2. In Table 2, “A” means cracking is not confirmed; “B” means cracking is confirmed. Because comparative composition 1 and 2 are evaluated as B in the cracking evaluation, compositions other than them are used for following further evaluations.

Measurement of Film Thickness

Film thickness of each metal oxide film is measured with its cross-section photograph of the wafer taken with JSM-7100F (JEOL Ltd). The measured results are shown in Table 2.

Evaluation of Ar Sputtering Resistance

The metal oxide film on the wafer is sputtered by apparatus K-Alpha Plus (Thermo Scientific) at the conditions of Ar gas, ion energy: 3 keV and 2 minutes.

Film thickness is measured as described above for the metal oxide film before sputtering and after sputtering. The thickness difference is obtained, and thickness decrease is calculated per unit time. The evaluation results are shown in Table 2.

Evaluation of Etch Resistance

The metal oxide film on the wafer is dry etched by etching apparatus NE-5000N (ULVAC) at the conditions of chamber pressure: 0.17 mT, RF power: 200 W, gas flow rate: CF₄ (50 sccm), Ar (35 sccm) and 02 (4 sccm), and time: 30 seconds.

Film thickness are measured as described above for the metal oxide film before etching and after etching. The thickness difference is obtained, and thickness decrease is calculated per unit time. The evaluation results are shown in Table 2.

TABLE 2

| | | | | Ar | |
|---|---|---|---|---|---|
| | | | Film | sputtering | Etch |
| | | | thickness | resistance | resistance |
| | Solubility | Crack | (nm) | (nm/min) | (nm/min) |
| Working Ex. | A | A | 232 | 11.7 | 17.8 |
| Composition. 1 | | | | | |
| Working Ex. | A | A | 256 | 11.5 | 17.4 |
| Composition 2 | | | | | |
| Working Ex. | A | A | 243 | 12.6 | 18.7 |
| Composition 3 | | | | | |
| Working Ex. | A | A | 241 | 11.6 | 17.7 |
| Composition 4 | | | | | |
| Comparative Ex. | A | B | — | — | — |
| Composition 1 | | | | | |
| Comparative Ex. | A | B | — | — | — |
| Composition 2 | | | | | |

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

1.-22. (canceled)

23. A spin coating composition comprising a carbon material (A), a metal organic compound (B), and solvent (C), wherein
(i) the carbon material (A) comprises unit (A1) represented by formula (A1): 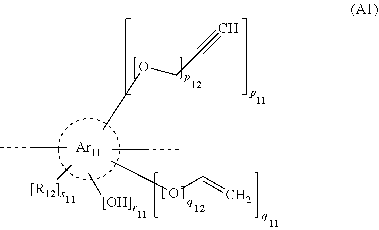
wherein:
Ar₁₁ is a C₆₋₆₀ hydrocarbon unsubstituted or substituted by Ru,
R₁₂ is a C₁₋₂₀ linear, branched or cyclic alkyl, amino, or alkylamino,
R₁₂ is I, Br or CN,
p₁₁ is an integer of 0-5, p₁₂ is an integer of 0-1, q₁₁ is an integer of 0-5, q₁₂ is an integer of 0-1, r₁₁ is an integer of 0-5, and s₁₁ is an integer of 0-5, and
provided that p₁₁, q₁₁ and r₁₁ do not take 0 at the same time;
(ii) the solvent (C) comprises an organic solvent; and
(iii) a mass ratio of the carbon material (A) to the mass of the metal organic compound (B) is approximately 5 to approximately 100 mass %.

24. The spin coating composition according to claim 23, wherein the formula (A1) is one or more of:
(i) formula (A1-1): 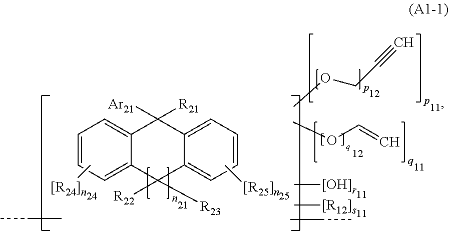
wherein
Ar₂₁ is a C₆₋₅₀ aromatic hydrocarbon ring,
R₂₁, R₂₂ and R₂₃ are each independently a C₆₋₅₀ aromatic hydrocarbon ring, hydrogen or single bond boding to another unit,
R₂₄ and R₂₅ each independently a C₁₋₄ alkyl, optionally plural R₂₄s and/or R₂₅s can bind each other to make aromatic ring with an adjacent benzene,
n₂₁ is an integer of 0-1, n₂₄ and n₂₅ are each independently an integer of 0-3, and
R₁₂ is I, Br or CN,
p₁₁ is an integer of 0-5, p₁₂ is an integer of 0-1, q₁₁ is an integer of 0-5, q₁₂ is an integer of 0-1, r₁₁ is an integer of 0-5, and s₁₁ is an integer of 0-5, and
provided that p₁₁, q₁₁ and r₁₁ do not take 0 at the same time;
(ii) formula (A1-2): 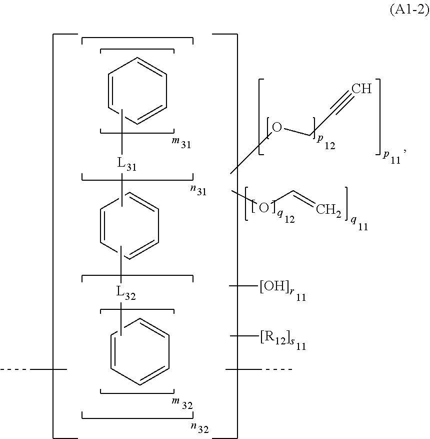
wherein
L₃₁ and L₃₂ are each independently a single bond or phenylene,
n₃₁, n₃₂, m₃₁ and m₃₂ are each independently an integer of 0-6,
R₁₂ is I, Br or CN,
p₁₁ is an integer of 0-5, p₁₂ is an integer of 0-1, q₁₁ is an integer of 0-5, q₁₂ is an integer of 0-1, r₁₁ is an integer of 0-5, and s₁₁ is an integer of 0-5, and
provided that p₁₁, q₁₁ and r₁₁ do not take 0 at the same time; and
(iii) formula (A1-3): 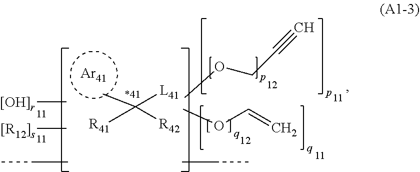
wherein:
Ar₄₁ is a C₆₋₅₀ aromatic hydrocarbon,
R₄₁ and R₄₂ are each independently a C₁₋₁₀ alkyl, optionally R₄₁ and R₄₂ constitute cyclic hydrocarbon,
the carbon atom at the *41 position is a quaternary carbon atom,
L₄₁ is a C₆-50 arylene, or a single bond bonding to another unit,
R₁₂ is I, Br or CN,
p₁₁ is an integer of 0-5, p₁₂ is an integer of 0-1, q₁₁ is an integer of 0-5, q₁₂ is an integer of 0-1, r₁₁ is an integer of 0-5, and s₁₁ is an integer of 0-5, and
provided that p₁₁, q₁₁ and r₁₁ do not take 0 at the same time; and
wherein when carbon material (A) is polymer, the polymer consists essentially of or consists of no secondary carbon atoms and tertiary carbon atoms except at a terminal position of the polymer.

25. The spin coating composition according to claim 23, wherein the carbon material (A) further comprises one or more of:
(iv) unit (A2) represented by formula (A2): 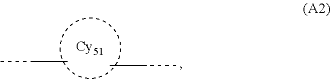
wherein Cy₅₁ is a C₅₋₃₀ cyclic hydrocarbon ring; and
(v) unit (A3) represented by formula (A3): 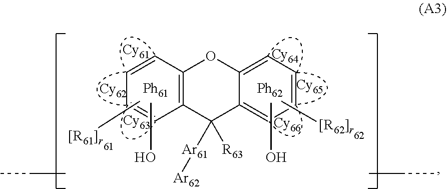
wherein:
Ar₆₁ is a single bond, C₁₋₆ alkyl, C₆₋₁₂ cycloalkyl, or C₆₋₁₄ aryl,
Ar₆₂ is a C₁₋₆ alkyl, C₆₋₁₂ cycloalkyl, or C₆₋₁₄ aryl,
R₆₁ and R₆₂ are each independently a C₁₋₆ alkyl, hydroxy, halogen, or cyano,
R₆₃ is a hydrogen, C₁₋₆ alkyl, or C₆₋₁₄ aryl,
when Ar₆₂ is a C₁₋₆ alkyl or C₆₋₁₄ aryl and R₆₃ is a C₁₋₆ alkyl or C₆₋₁₄ aryl, Ar₆₂ and R₆₃ are optionally linked to each other to form a hydrocarbon ring,
r₆₁ and r₆₂ are each independently an integer of 0-5,
at least one of the Cy₆₁, Cy₆₂, and Cy₆₃ rings surrounded by the broken line is an aromatic hydrocarbon ring fused with the adjacent aromatic hydrocarbon ring Ph₆₁, and
at least one of the Cy₆₄, Cy₆₅, and Cy₆₆ rings surrounded by the broken line is an aromatic hydrocarbon ring fused with the adjacent aromatic hydrocarbon ring Ph₆₂.

26. The spin coating composition according to claim 23, wherein the metal organic compound (B) is a metal organic complex comprising a hydrolyzable group, a hydrolyzed product of an metal organic complex comprising a hydrolyzable group, a hydrolysis-condensation product of an metal organic complex comprising a hydrolyzable group, or any combination of any of these.

27. The spin coating composition according to claim 23, wherein the metal organic compound (B) is represented by below formula (B); 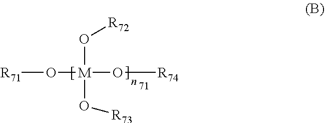
wherein:
M is a metal having a valence of four (4) and is at least one selected from the group consisting of Zr, Ta, Hf, Ti, Sn, Pb, Nb, Mo, Ge and W,
n₇₁ is number of 1 to 20, and
R₇₁, R₇₂, R₇₃ and R₇₄ are each independently selected from the group consisting of:
(a) a first organic moiety (B)-1 represented by formula (B)-1: 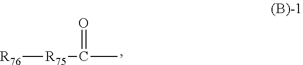
wherein:
R₇₅ is selected from the group consisting of a C₂₋₁₀ alkylene, C₃₋₁₂ branched alkylene, C₅₋₁₂ cycloalkylene, C₂₋₁₀ alkylene containing a C═C double bond, C₃₋₁₂ branched alkylene containing a C═C double bond, and C₅₋₁₂ cycloalkylene containing a C═C double bond, and
R₇₆ is a hydrogen or alkyloxycarbonyl represented by a formula (B)-1-1: 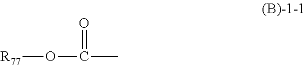
wherein R₇₇ is a C₁₋₈ alkyl;
(b) a silicon bearing organic moiety having at least 2 carbons (B)-2 represented by formula (B)-2: 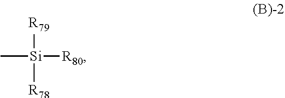
wherein:
R₇₈ and R₇₉ are each independently selected from the group consisting of a C₁₋₈ alkyl, C₃₋₁₂ branched alkyl, C₁₋₈ alkyloxy, C₃₋₁₂ branched alkyloxy, and C₆₋₁₆ aryl;
R₈₀ is selected from the group consisting of a C₁₋₈ alkyl, C₆₋₁₆ aryl, hydroxyl and siloxane having the structure (B)-2-1: 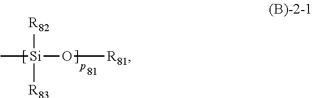
wherein:
R₈₁ is selected from the group consisting of a hydrogen, C₁₋₈ alkyl, C₁₋₈ alkyl substituted with a hydroxyl, a C₆₋₁₆ aryl, and a silyl moiety having structure (B)-2-1-1: 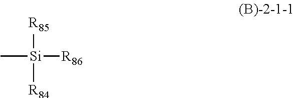
wherein: R₄ and R₈₅ are each independently selected from the group consisting of C₁₋₈ alkyl, C₃₋₁₂ branched alkyl, C₁₋₈ alkyloxy, C₃₋₁₂ branched alkyloxy, and C₆₋₁₆ aryl; and R₆ is selected from the group consisting of C₁₋₈ alkyl, and C₆₋₁₆ aryl;
R₈₂ and R₈₃ are each independently selected from the group consisting of C₁₋₈ alkyl, C₃₋₁₂ branched alkyl, C₁₋₈ alkyloxy, C₃₋₁₂ branched alkyloxy, and C₆₋₁₆ aryl; and psi represents the number of repeat units in the siloxane moiety (B)-2-1; and
(c) a second organic moiety selected from the group consisting of a C₂₋₈ alkyl, C₂₋₈ alkyl carboxyl, C₆₋₂₀ aryl carboxyl, fluorenyl carboxyl, fluorinated C₂₋₈ alkyl carboxyl, C₂₋₈ alkyl sulfonyl, fluorinated C₂₋₈ alkyl sufonyl, and any combination of any of these, and
(d) any combination of (a), (b) and (c).

28. The spin coating composition according to claim 23, wherein solvent (C) is selected from the group consisting of an aliphatic hydrocarbon solvent, aromatic hydrocarbon solvent, monoalcohol solvent, polyol solvent, ketone solvent, ether solvent, ester solvent, nitrogen-containing solvent, sulfur-containing solvent, and any combination of any of these.

29. The spin coating composition according to claim 23, further comprising surfactant (D); and
optionally further comprising another additive (E) selected from the group consisting of a cross linker, acid generator, radical generator, photo polymerization initiator, an agent for enhancing adhesion to substrates, an anti-foaming agent and combinations thereof.

30. The spin coating composition according to claim 23, wherein a molecular weight of the carbon material (A) is approximately 500 to approximately 4,000.

31. The spin coating composition according to claim 23, wherein a mass ratio of the metal organic compound (B) to the total mass of the spin coating composition is approximately 5 to approximately 100 mass %;
wherein a mass ratio of the solvent (C) to the total mass of the spin coating composition is approximately 5 to approximately 100 mass %; and
wherein a mass ratio of the surfactant (D) to the mass of the metal organic compound (B) is approximately 5 to approximately 100 mass %.

32. A spin on metal hard mask composition consisting of the spin coating composition according to claim 23.

33. A method of manufacturing method a metal oxide film comprising
(1) spin coating the spin coating composition according to claim 23 above a substrate; and
(2) heating the spin coating composition to make a metal oxide film, wherein the heating is preferably performed at approximately 200 to approximately 800° C. and/or approximately 30 to approximately 240 seconds.

34. The method according to claim 33, wherein a metal content of the metal oxide film is approximately 10 to approximately 85 mass % to the total mass of the film.

35. A method of manufacturing a resist coating comprising:
applying a resist composition above the metal oxide film manufactured by the method according to claim 33.

36. A method of manufacturing resist patterns comprising:
(1) exposing the resist coating manufactured by the method according to claim 35 to radiation light;
(2) developing the exposed resist coating with a developer; and
(3) removing the developer from the substrate.

37. A method of manufacturing a processed substrate comprising:
(1) etching the resist patterns manufactured by the method according to claim 36; and
(2) processing the substrate.

38. A method of manufacturing a device comprising:
(1) forming wiring in the processed substrate manufactured by the method according to claim 37, wherein the substrate is a stepped substrate.

39. The spin coating composition of claim 23, wherein the spin coating composition consists essentially of a carbon material (A), a metal organic compound (B), and solvent (C).

40. The spin coating composition of claim 23, wherein the spin coating composition consists essentially of a carbon material (A), a metal organic compound (B), solvent (C) and a surfactant (D).

41. The spin coating composition of claim 23, wherein the spin coating composition consists essentially of a carbon material (A), a metal organic compound (B), solvent (C), surfactant (D) and an additive (E) selected from the group consisting of a cross linker, acid generator, radical generator, photo polymerization initiator, an agent for enhancing adhesion to substrates, an anti-foaming agent and combinations thereof.

42. The spin coating composition of claim 23, wherein the spin coating composition consists of a carbon material (A), a metal organic compound (B), and solvent (C).

43. The spin coating composition of claim 29, wherein the spin coating composition consists of a carbon material (A), a metal organic compound (B), solvent (C) and surfactant (D).

44. The spin coating composition of claim 29, wherein the spin coating composition consists of a carbon material (A), a metal organic compound (B), solvent (C), surfactant (D) and an additive (E) selected from the group consisting of a cross linker, acid generator, radical generator, photo polymerization initiator, an agent for enhancing adhesion to substrates, an anti-foaming agent and combinations thereof.
